(19) United States
(12) Patent Application Publication
(10) Pub. No.: US 2016/0190375 A1
(43) Pub. Date: Jun. 30, 2016

(54) HETERO-JUNCTION SOLAR CELL AND MANUFACTURING METHOD THEREOF

(71) Applicant: NEO SOLAR POWER CORP., Hsinchu (TW)

(72) Inventor: Peng CHEN, Hsinchu (TW)

(21) Appl. No.: 14/672,824

(22) Filed: Mar. 30, 2015

(30) Foreign Application Priority Data
Dec. 31, 2014 (TW) 103146509

(51) Int. Cl. H01L 31/0687; H01L 31/068; H01L 31/18; H01L 31/0224; H01L 31/0376; H01L 31/20

(52) U.S. Cl. CPC H01L 31/0687; H01L 31/03762; H01L 31/202; H01L 31/1884; H01L 31/208; H01L 31/022466; H01L 31/0684

(57) ABSTRACT

A hetero junction solar cell includes a semiconductor substrate, a first n-type buffer layer, a second n-type buffer layer, a first amorphous silicon layer, a second amorphous silicon layer, a first TCO layer and a second TCO layer. The first n-type buffer layer and the second n-type buffer layer are formed respectively on a first surface and a second surface of the semiconductor substrate. The first amorphous silicon layer and the second amorphous silicon layer are formed respectively on the first n-type buffer layer and the second n-type buffer layer. The first TCO layer and the second TCO layer are formed respectively on the first amorphous silicon layer and the second amorphous silicon layer.

This application claims the benefit of Taiwan Patent Application Serial No. 103146509 filed on Dec. 31, 2014, the subject matter of which is incorporated herein by reference.

### BACKGROUND OF INVENTION

1. Field of the Invention

The invention relates to a hetero junction solar cell and a manufacturing method thereof, and more particularly to the hetero junction solar cell and the method for producing the same that introduce an n-type amorphous silicon layer to act as a buffer layer.

2. Description of the Prior Art

Referring now to FIG. 1, a conventional hetero junction solar cell in the art is schematically shown. As shown, the conventional hetero junction solar cell PA100 includes a semiconductor substrate PA1, a first intrinsic amorphous silicon layer PA2, a second intrinsic amorphous silicon layer PA3, a first amorphous silicon layer PA4, a second amorphous silicon layer PA5, a first TCO layer PA6, a second TCO layer PA7, at least one first conductive line PA8 (one labeled in the figure), and at least one second conductive line PA9 (one labeled in the figure).

The semiconductor substrate PA1 doped as a first type semiconductor (for example, an n-type semiconductor) is typical a crystal silicon semiconductor substrate. The first intrinsic amorphous silicon layer PA2 and the second intrinsic amorphous silicon layer PA3 are respectively formed to opposing sides of the semiconductor substrate PA1.

The first amorphous silicon layer PA4 formed on top of the first intrinsic amorphous silicon layer PA2 is doped by the first type semiconductor. The second amorphous silicon layer PA5 formed on top of the second intrinsic amorphous silicon layer PA3 is doped by a second type semiconductor (for example, a p-type semiconductor). In this conventional solar cell, by providing the corresponding intrinsic amorphous silicon layers topped by the corresponding amorphous silicon layers doped respectively by the first type semiconductor and the second type semiconductor to the opposing sides of the crystal silicon semiconductor substrate, a double-layered hetero-junction layer can be formed to effectively enhance the photovoltaic conversion efficiency of the solar cell.

Nevertheless, in practice, for the first intrinsic amorphous silicon layer PA2 and the second intrinsic amorphous silicon layer PA3 usually contain dispersing defects, the movement of the electrons and the electron holes would be adversely affected. In order to resolve problems caused by these defects in the intrinsic amorphous silicon layers, a plasma treatment which contains a hydrogen is applied to introduce a high-concentrated hydrogen to combine the dangling bond and the hydrogen ion of the intrinsic amorphous silicon while in depositing the intrinsic layer, such that the in-layer defects can be reduced.

In addition, in some applications, the intrinsic layer is doped slightly by an n-type semiconductor or a p-type semiconductor, so that the overall resistance of the hetero-junction solar cell can be reduced. However, though reduced doping might reduce the overall resistance, yet the density of interface state is increased as well.

### SUMMARY OF THE INVENTION

In view of the aforesaid prior art, the hetero junction structure is usually produced by forming the intrinsic layers and the amorphous silicon layers to opposing sides of the crystal silicon semiconductor substrate, thereby the internal electric field can be induced, and the open-circuit voltage of the solar cell can be raised. However, due to poor electric conductivity and high electric resistance of the intrinsic layer itself, the field effect passivation thereof would be dim, and thus power of the hetero junction solar cell would be limited.

To improve such a problem, the hydrogen plasma treatment (HPT) is introduced to reduce the density of interface as well as the resistance value of the intrinsic layer, or the light doping process is applied to reduce the resistance value so as to enhance the field effect. However, all these resorts would lead to the increase of the defect of interface.

Accordingly, it is the primary object of the present invention to provide a hetero junction solar cell and a manufacturing method thereof, in which an n-type buffer layer is introduced to replace the intrinsic layer so as to reduce the defect of interface and the resistance value, but to enhance the passivation of the field effect.

In the present invention, the hetero-junction solar cell includes a semiconductor substrate, a first n-type buffer layer, a second n-type buffer layer, a first amorphous silicon layer, a second amorphous silicon layer, a first TCO layer and a second TCO layer. The semiconductor substrate has a first surface and a second surface opposite to the first surface, and is doped by a first type semiconductor.

The first n-type buffer layer formed on the first surface includes a first n-type amorphous silicon layer and a second n-type amorphous silicon layer. The first n-type amorphous silicon layer directly formed on the first surface is doped by an n-type semiconductor with a dopant concentration ranged from 1×10¹⁴ to 1×10¹⁶ atoms/cm³. The second n-type amorphous silicon layer is then formed on the first n-type amorphous silicon layer.

The second n-type buffer layer formed on the second surface includes a third n-type amorphous silicon layer and a fourth n-type amorphous silicon layer. The third n-type amorphous silicon layer is formed directly on the second surface. The third n-type amorphous silicon is doped by an n-type semiconductor with a dopant concentration ranged from 1×10¹⁴ to 1×10¹⁶ atoms/cm³. The fourth n-type amorphous silicon layer is formed on the third n-type amorphous silicon layer.

The first amorphous silicon layer formed on the first n-type buffer layer is doped by a second type semiconductor. The second amorphous silicon layer formed on the second n-type buffer layer is doped by the first type semiconductor. The first TCO layer is formed on the first amorphous silicon layer, and the second TCO layer is formed on the second amorphous silicon layer.

In the present invention, the first n-type buffer layer and the second n-type buffer layer are introduced to replace the intrinsic semiconductor layers. For the first n-type buffer layer and the second n-type buffer layer are both doped by the n-type semiconductors, so the overall electric resistance can be reduced, and the performance in field effect can be enhanced. In addition, for the first n-type amorphous silicon layer and the third n-type amorphous silicon layer are layers treated by hydrogen plasma, so the defect of interface for the first n-type buffer layer and the second n-type buffer layer can be reduced, thereby the interfacial compound electric current can be reduced, and the open-circuit voltage can be improved.

In one embodiment of the present invention, the first n-type buffer layer has a thickness ranged from 1 nm to 15 nm. Preferably, the first n-type amorphous silicon layer has a thickness ranged from 0.9 nm to 10 nm, and the second n-type amorphous silicon layer has a thickness no less than 0.1 nm.

In one embodiment of the present invention, the second n-type buffer layer has a thickness ranged from 1 nm to 15 nm. Preferably, the third n-type amorphous silicon layer has a thickness ranged from 0.9 nm to 10 nm, and the fourth n-type amorphous silicon layer has a thickness no less than 0.1 nm.

In one embodiment of the present invention, one of the first type semiconductor and the second type semiconductor is an n-type semiconductor, while another one thereof is a p-type semiconductor.

In the present invention, the manufacturing method of the hetero junction solar cell includes the following steps: (a) providing a semiconductor substrate doped by a first type semiconductor; (b) forming a first n-type buffer layer on a first surface of the semiconductor substrate; (c) forming a second n-type buffer layer on a second surface of the semiconductor substrate; (d) forming a first amorphous silicon layer doped by a second type semiconductor on the first n-type buffer layer; (e) forming a second amorphous silicon layer doped by the first type semiconductor on the second n-type buffer layer; (f) forming a first TCO layer on the first amorphous silicon layer; and (g) forming a second TCO layer on the second amorphous silicon layer.

In one embodiment of the present invention, the step (b) can further include a step (b1) and a step (b2), in which the step (b1) is to form a first n-type amorphous silicon layer of the first n-type buffer layer on the first surface of the semiconductor substrate, and the step (b2) is to form a second n-type amorphous silicon layer of the first n-type buffer layer on the first n-type amorphous silicon layer, and the step (b2) is to form a second n-type amorphous silicon layer of the first n-type buffer layer on the first n-type amorphous silicon layer. Preferably, after the step (b1), a step (b11) is included to apply a doping gas to treat the first n-type amorphous silicon layer, in which the doping gas includes at least one of phosphine gas, arsine, nitrogen and hydrogen.

In one embodiment of the present invention, the step (c) can further include a step (c1) and a step (c2), in which the step (c1) is to form a third n-type amorphous silicon layer of the second n-type buffer layer on the second surface of the semiconductor substrate, and the step (c2) is to form a fourth n-type amorphous silicon layer of the second n-type buffer layer on the second n-type amorphous silicon layer. Preferably, after the step (c1), a step (c11) is included to apply a doping gas to treat the third n-type amorphous silicon layer, in which the doping gas includes at least one of phosphine gas, arsine, nitrogen and hydrogen.

### BRIEF DESCRIPTION OF THE DRAWINGS

The present invention will now be specified with reference to its preferred embodiment illustrated in the drawings, in which:

FIG. 1 is a schematic view of a conventional hetero-junction solar cell;

FIG. 2 is a schematic view of the preferred hetero junction solar cell in accordance with the present invention; and

FIG. 3A and FIG. 3B are together to show a flowchart of the preferred manufacturing method of the hetero junction solar cell in accordance with the present invention.

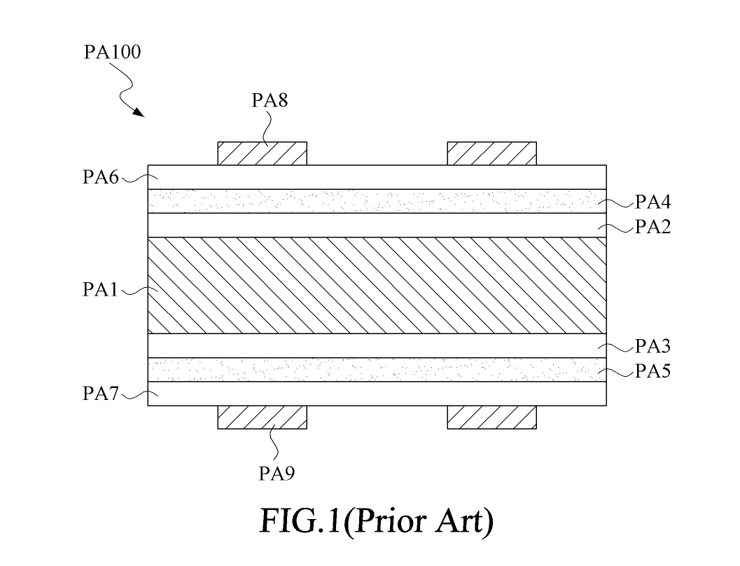

### DESCRIPTION OF THE PREFERRED EMBODIMENT

The invention disclosed herein is directed to a hetero junction solar cell and a manufacturing method thereof. In the following description, numerous details are set forth in order to provide a thorough understanding of the present invention. It will be appreciated by one skilled in the art that variations of these specific details are possible while still achieving the results of the present invention. In other instance, well-known components are not described in detail in order not to unnecessarily obscure the present invention.

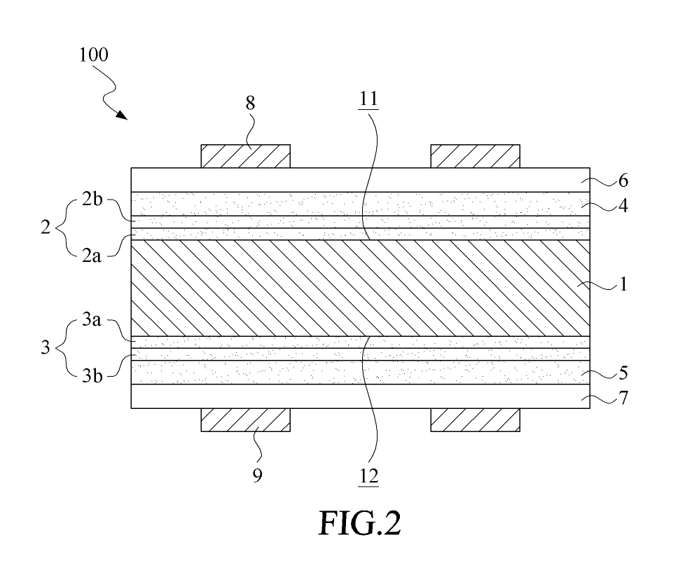

Referring to FIG. 2, a schematic view of the preferred hetero junction solar cell in accordance with the present invention is shown. As shown, the hetero junction solar cell 100 includes a semiconductor substrate 1, a first n-type buffer layer 2, a second n-type buffer layer 3, a first amorphous silicon layer 4, a second amorphous silicon layer 5, a first TCO layer 6, a second TCO layer 7, a plurality of first leads 8 and a plurality of second leads 9.

The semiconductor substrate 1 has a first surface 11 and a second surface 12 opposite to the first surface 11, and is doped by a first type semiconductor, in which the first type semiconductor can be a an n-type semiconductor or a p-type semiconductor. Preferably, in this embodiment, the first type semiconductor is an n-type semiconductor.

The first n-type buffer layer 2 formed on the first surface 11 includes a first n-type amorphous silicon layer 2a and a second n-type amorphous silicon layer 2b, in the first n-type buffer layer 2 has a thickness ranged from 1 nm to 15 nm.

The first n-type amorphous silicon layer 2a directly formed on the first surface 11 has a thickness ranged from 0.9 nm to 10 nm. The second n-type amorphous silicon layer 2b formed on the first n-type amorphous silicon layer 2a has a thickness no less than 0.1 nm. In the present invention, the first n-type amorphous silicon layer 2a is a layer treated by hydrogen plasma. Namely, while in forming the first n-type amorphous silicon layer 2a, a hydrogen plasma treatment is applied to modify and thus form a layer treated by hydrogen plasma, such that the first n-type amorphous silicon layer 2a can then be doped by hydrogen ions with a dopant concentration ranged from 1×10¹⁴ to 1×10¹⁶ atoms/cm³. However, in other embodiments, the modified layer can be formed by phosphine gas, arsine, nitrogen, or any gas the like. In other embodiments, the first n-type amorphous silicon layer 2a may have a thickness ranged from 1 nm to 10 nm, and the second n-type amorphous silicon layer 2b has a thickness no less than 0.1 nm. Thereby, the first n-type buffer layer 2 can have a thickness ranged from 1.1 nm to 15 nm.

The second n-type buffer layer 3 formed on the second surface 12 includes a third n-type amorphous silicon layer 3a and a fourth n-type amorphous silicon layer 3b. In the present invention, the second n-type buffer layer 3 has a thickness ranged from 1 nm to 15 nm.

The third n-type amorphous silicon layer 3a is formed on the second surface 12, and the fourth n-type amorphous silicon layer 3b is formed on the third n-type amorphous silicon layer 3a. The third n-type amorphous silicon layer 3a is a layer treated by hydrogen plasma with a thickness ranged from 0.9 nm to 10 nm and a dopant concentration of hydrogen ions ranged from 1×10¹⁴ to 1×10¹⁶ atoms/cm³. Namely, while in forming the third n-type amorphous silicon layer 3a, a hydrogen plasma treatment is applied to modify and thus form a layer treated by hydrogen plasma. In other embodiments, the third n-type amorphous silicon layer 3a may have a thickness ranged from 1 nm to 10 nm, and the fourth n-type amorphous silicon layer 3b may have a thickness no less than 0.1 nm, such that the second n-type buffer layer 3 can have a thickness ranged from 1.1 nm to 15 nm.

The first amorphous silicon layer 4 is formed on the first n-type amorphous silicon layer 2a of the first n-type buffer layer 2, and is doped by a second type semiconductor. The second type semiconductor can be an n-type semiconductor or a p-type semiconductor. In this embodiment, the second type semiconductor is a p-type semiconductor.

The second amorphous silicon layer 5 is formed on the third n-type amorphous silicon layer 3a of the second n-type buffer layer 3, and is doped by a first type semiconductor.

The first TCO layer 6 is formed on the first amorphous silicon layer 4, and the second TCO layer 7 is formed on the second amorphous silicon layer 5. As shown, further on the first TCO layer 6, a plurality of the first leads 8 (one labeled in the figure) is constructed.

Similarly, on the second TCO layer 7, a plurality of the second leads 9 (one labeled in the figure) is constructed.

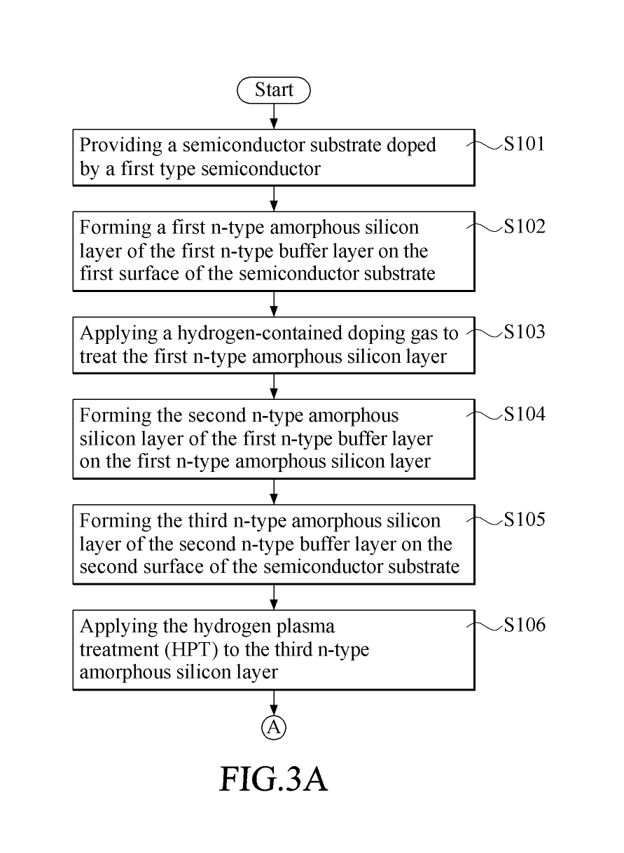

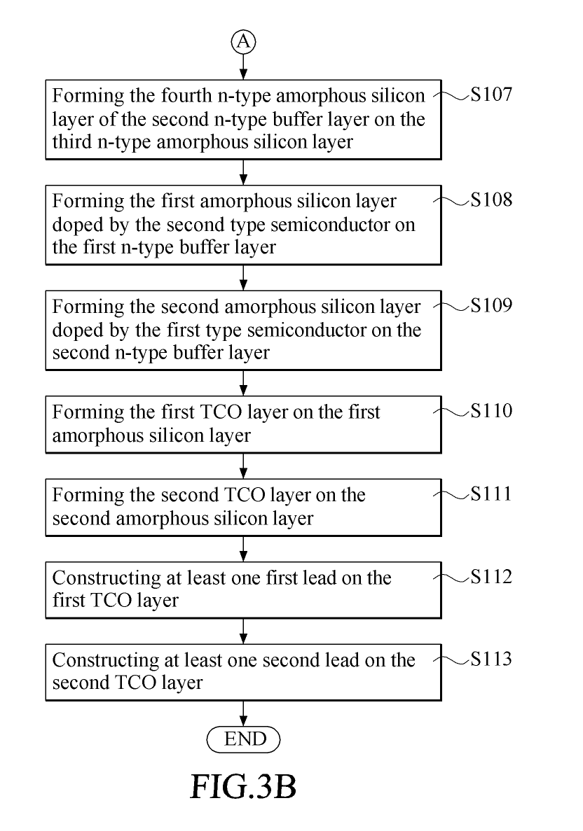

Refer now to FIG. 2, FIG. 3A and FIG. 3B, in which FIG. 3A and FIG. 3B are together to show a flowchart of the preferred manufacturing method of the hetero-junction solar cell in accordance with the present invention. As shown, the manufacturing method of the hetero junction solar cell 100 includes the following steps.

Step S101: Provide a semiconductor substrate 1 doped by a first type semiconductor.

Step S102: Form a first n-type amorphous silicon layer 2a of the first n-type buffer layer 2 on the first surface 11 of the semiconductor substrate 1.

Step S103: Apply a hydrogen-contained doping gas to treat the first n-type amorphous silicon layer 2a so as to perform a hydrogen plasma treatment (HPT) on the first n-type amorphous silicon layer 2a. In the present invention, the first n-type amorphous silicon layer 2a is typically formed by a chemical vaporous deposition, and, while in depositing, the doping of the n-type semiconductor is performed simultaneously. In addition, the hydrogen plasma treatment (HPT) performs the modification by introducing a high-concentrated hydrogen during the deposition process so as to obtain a hydrogen plasma treatment (HPT) layer with a thickness ranged from 0.9 nm to 10 nm and a dopant concentration ranged from 1×10¹⁴ to 1×10¹⁶ atoms/cm³. Thereby, the hydrogen ion can effectively passivate the dangling bond of the first n-type amorphous silicon layer 2a so as to reduce the density of interface and the surface recombination.

Step S104: Form the second n-type amorphous silicon layer 2b of the first n-type buffer layer 1 on the first n-type amorphous silicon layer 2a. The second n-type amorphous silicon layer 2b is similarly obtained by a chemical vaporous deposition. While in depositing, the n-type semiconductor is doped simultaneously.

Step S105: Form the third n-type amorphous silicon layer 3a of the second n-type buffer layer 3 on the second surface 12 of the semiconductor substrate 1.

Step S106: Apply the hydrogen plasma treatment (HPT) to the third n-type amorphous silicon layer 3a. In the present invention, the third n-type amorphous silicon layer 3a is typically formed by a chemical vaporous deposition, and, while in depositing, the doping of the n-type semiconductor is performed simultaneously. In addition, the hydrogen plasma treatment (HPT) performs the modification by introducing a high-concentrated hydrogen during the deposition process, such that the hydrogen ions can combine the dangling bonds of the third n-type amorphous silicon layer 3a so as to reduce the density of interface state.

Step S107: Form the fourth n-type amorphous silicon layer 3b of the second n-type buffer layer 3 on the third n-type amorphous silicon layer 3a. The fourth n-type amorphous silicon layer 3b is similarly obtained by a chemical vaporous deposition. While in depositing, the n-type semiconductor is doped simultaneously.

Step S108: Form the first amorphous silicon layer 4 doped by the second type semiconductor on the first n-type buffer layer 2.

Step S109: Form the second amorphous silicon layer 5 doped by the first type semiconductor on the second n-type buffer layer 3.

In the present invention, the Step S108 and the Step S109 are exchangeable in order.

Step S110: Form the first TCO layer 6 on the first amorphous silicon layer 4.

Step S111: Form the second TCO layer 7 on the second amorphous silicon layer 5.

In the present invention, the Step S110 and the Step S111 are exchangeable in order.

Step S112: Construct at least one first lead 8 on the first TCO layer 6.

Step S 113: Construct at least one second lead 9 on the second TCO layer 7.

In the present invention, the Step S112 and the Step S113 are exchangeable in order.

In summary, by compared to the prior art that uses the hydrogen plasma treatment (HPT) to reduce the density of interface state of the intrinsic layer or reduce the resistance value by lightly doped intrinsic layer, and to enhance the passivation effect of the field effect. The present invention utilizes the first n-type buffer layer and the second n-type buffer layer to replace the conventional intrinsic semiconductor layers. Upon such an arrangement in the present invention, the first n-type buffer layer and the second n-type buffer layer with slight dopants can have a reduced resistance value and express a enhanced passivation of the field effect. In addition, the present invention further separates the first n-type buffer layer and the second n-type buffer layer, and, while in forming the first n-type amorphous silicon layer and the third n-type amorphous silicon layer, the hydrogen plasma treatment (HPT) is applied to reduce the corresponding density of interface state. Thus, by compared to the prior art, the present invention can use light doping upon the first n-type buffer layer and the second n-type buffer layer so as to reduce the overall electric resistance and enhance the passivation of the field effect. Further, for the first n-type amorphous silicon layer and the third n-type amorphous silicon layer are modified by the hydrogen ions, so the density of interface state in the first n-type buffer layer and the second n-type buffer layer can be substantially reduced, and thus the overall resistance value of the hetero junction solar cell can be successfully improved.

While the present invention has been particularly shown and described with reference to a preferred embodiment, it will be understood by those skilled in the art that various changes in form and detail may be without departing from the spirit and scope of the present invention.

What is claimed is:

1. A hetero-junction solar cell, comprising:
a semiconductor substrate, having a first surface and a second surface opposing to the first surface, doped by a first type semiconductor;
a first n-type buffer layer, formed on the first surface, further comprising:
a first n-type amorphous silicon layer, formed on the first surface, doped by an n-type semiconductor with a dopant concentration ranged from 1×10¹⁴ to 1×10¹⁶ atoms/cm³; and
a second n-type amorphous silicon layer, formed on the first n-type amorphous silicon layer;
a second n-type buffer layer, formed on the second surface, further comprising:
a third n-type amorphous silicon layer, formed on the second surface, doped by another n-type semiconductor with a dopant concentration ranged from 1×10¹⁴ to 1×10¹⁶ atoms/cm³; and
a fourth n-type amorphous silicon layer, formed on the third n-type amorphous silicon layer;
a first amorphous silicon layer, formed on the first n-type buffer layer, doped by a second type semiconductor;
a second amorphous silicon layer, formed on the second n-type buffer layer, doped by the first type semiconductor;
a first transparent conductive oxide layer, formed on the first amorphous silicon layer; and
a second transparent conductive oxide layer, formed on the second amorphous silicon layer.

2. The hetero junction solar cell of claim 1, wherein the first n-type buffer layer has a thickness ranged from 1 nm to 15 nm.

3. The hetero-junction solar cell of claim 2, wherein the thickness of the first n-type amorphous silicon layer is from 0.9 nm to 10 nm, and the thickness of the second n-type amorphous silicon layer is at least 0.1 nm.

4. The hetero-junction solar cell of claim 1, wherein the thickness of the second n-type buffer layer is from 1 nm to 15 nm.

5. The hetero-junction solar cell of claim 4, wherein the thickness of the third n-type amorphous silicon layer is from 0.9 nm to 10 nm, and the thickness of the fourth n-type amorphous silicon layer is at least 0.1 nm.

6. The hetero junction solar cell of claim 1, wherein one of the first type semiconductor and the second type semiconductor is an n-type semiconductor, while another one thereof is a p-type semiconductor.

7. A manufacturing method of a hetero junction solar cell, comprising the steps of:
(a) providing a semiconductor substrate doped by a first type semiconductor;
(b) forming a first n-type buffer layer on a first surface of the semiconductor substrate;
(c) forming a second n-type buffer layer on a second surface of the semiconductor substrate;
(d) forming a first amorphous silicon layer doped by a second type semiconductor on the first n-type buffer layer;
(e) forming a second amorphous silicon layer doped by the first type semiconductor on the second n-type buffer layer;
(f) forming a first transparent conductive oxide layer on the first amorphous silicon layer; and
(g) forming a second transparent conductive oxide layer on the second amorphous silicon layer.

8. The manufacturing method of a hetero junction solar cell of claim 7, wherein the step (b) further includes the steps of:
(b1) forming a first n-type amorphous silicon layer of the first n-type buffer layer on the first surface of the semiconductor substrate; and
(b2) forming a second n-type amorphous silicon layer of the first n-type buffer layer on the first n-type amorphous silicon layer.

9. The manufacturing method of a hetero junction solar cell of claim 8, wherein a step (b11) of treating the first n-type amorphous silicon layer by a doping gas is performed after the step (b1).

10. The manufacturing method of a hetero-junction solar cell of claim 9, wherein the doping gas includes at least one of phosphine gas, arsine, nitrogen and hydrogen.

11. The manufacturing method of a hetero-junction solar cell of claim 7, wherein the step (c) further includes the steps of:
(c1) forming a third n-type amorphous silicon layer of the second n-type buffer layer on the second surface of the semiconductor substrate; and
(c2) forming a fourth n-type amorphous silicon layer of the second n-type buffer layer on the second n-type amorphous silicon layer.

12. The manufacturing method of a hetero junction solar cell of claim 11, wherein a step (c11) of treating the third n-type amorphous silicon layer by a doping gas is performed after the step (c1).

13. The manufacturing method of a hetero-junction solar cell of claim 12, wherein the doping gas includes at least one of phosphine gas, arsine, nitrogen and hydrogen.
